(19) United States
(12) Patent Application Publication
(10) Pub. No.: US 2005/0117424 A1
(43) Pub. Date: Jun. 2, 2005

(54) Low power sensing scheme for the semiconductor memory

(76) Inventor: Chih-Ta Star Sung, Glonn (DE)

Correspondence Address: Chih-Ta Star Sung;RM. 308, BLD. 52, NO. 195, CHUNG HSING RD., SEC. 4, CHU TUNG TOWNSHIP, HSINCHU COUNTY, 310, TW

(21) Appl. No.: 10/724,492

(22) Filed: Dec. 1, 2003

(51) Int. Cl. G11C 7/00

(52) U.S. Cl. 365/205

(57) ABSTRACT

The present invention provides a sensing scheme for semiconductor memory. N-type devices coupling between ground and a bit line and a bit line-bar of memory cells quickly discharge a bit line and a bit line-bar during non-accessing mode. During data accessing mode, one P-type device of an SRAM memory cell pulls up bit line or bit line-bar node slowly to minimize the inductive coupling noise and VDD, Ground bouncing, hence allows smaller amount of differential voltage input to the sense amplifier and results in lower power consumption. A self-timer counts the needed time and sends a signal to enable the current driven sense amplifier and to pull down the word line to avoid further pulling up the bit line or bit line-bar voltage and to reduce the power dissipation. A delay device coupling between the self-timer and bit line and bit line-bar avoids overlapping of pull-down and word line and reduces power leakage.

### BACKGROUND OF THE INVENTION

1. Field of Invention

This invention relates generally to a semiconductor memory sensing scheme. In particular, it relates to a pre-charging circuit for memory data accessing which connects to bit line and bit line-bar of semiconductor memory array which helps in reducing power consumption during accessing the memory cell.

2. Description of Related Art

A semiconductor memory is typically comprised of an array of memory cells which are aligned in rows and columns as shown in FIG. 1. A memory cell 14 is used to store data for future use. For efficiency, a memory array includes a large amount of memory cells 14. A WL 15 runs through top of hundreds or even thousands of memory cell gates which makes the WL 15 capacitance load quite large and needs a big driver 13 to turn on the WL 15.

In an CMOS circuit, “Ground, or 0V” is mostly commonly used to represent a logic “0”, while a “Supply voltage, VDD” is mostly commonly used to represent a logic “1”, Data accessing of a memory cell is done by applying an input voltage to a selected word line, WL or a row, and a selected bit line, BL or a column. The word line selection is done by a word line decoder 12 and a word line driver 13. A column decoder 17 selects the output bit of a memory array. A sense amplifier 16 is commonly implemented to quickly convert the voltage difference between BL 18 and BL-Bar 19 into a logic level of “0” or “1” with a shorter time delay.

For the consideration of silicon die area and cost, a memory array comprises a large amount of memory cells which makes capacitive load higher and might slow down the accessing time if no high speed sensing scheme is implemented to reduce the time delay, For the consideration of performance and silicon area, the bit lines, BL 25, 18, and BL-Bar 26, 19 are typically pre-charged to a predetermined voltage, for example to the VDD, a power supply level when no operation of memory accessing, and the N-type pull-down device 24 starts sinking current 23 when the word line is turned on. An N-type device has in principle half of intrinsic resistance compared to a P-type device which causes the saving of SRAM cell area and faster in differentiating the BL and BL-bar which are the input voltage to the sense amplifier.

FIG. 2a depicts the most commonly used prior art sensing scheme of a memory accessing. An SRAM cell 222 is used as an example. An SRAM cell has a back-to-back CMOS inverter gates with two pass transistors for accessing shown in FIG. 2a. A pre-charging signal is applied to the gates of P-type pull-up transistors 21, 22. When a memory cell is no longer being accessed, the pre-charge signal becomes low and turns on the pull-up devices 21, 22 which pull bit line and bit line-bar all the way up to VDD. During reading, the pre-charging signal shuts off the P-type pull-up devices 21, 22. The word line is driven high and turns on the memory cell 222. One of the two N-type devices 24a, 24b starts sinking the current if its gate is on high voltage. The other node DB, connecting to the BL through a pass transistor will keep the same logic “High” state since node DB the BL have the same voltage level.

The sense amplifier 27 senses whether the bit line is above or below a predetermined voltage. The sense amplifier generates an output that is at one level of two voltage potentials. The first voltage potential corresponds with the voltage difference between the bit line and the bit line-bar being at a voltage level no less than a predetermined voltage. And the second voltage potential corresponds with the voltage difference between the bit line and the bit line-bar being at a voltage level less than a predetermined voltage. In a practical case, the output voltage of a sense amplifier swings from “Ground” to “Supply, VDD”. FIG. 2b depicts the timing of word line turning on 280 and the sense amplifier enabling. When a bit line voltage 28 and a bit line-bar 29 are differentiated by discharging the bit line-bar to reach a predetermined threshold voltage 288, the sense amplifier 27 is supposed to be able to output a stable potential voltage and the current sensing mechanism is enabled 281.

The design of a sense amplifier generally includes consideration of several performance characteristics. Typically, the most important performance characteristics are speed of operation and power dissipation. That is, it is desirable that the sense amplifier sense the bit line voltage difference as quickly as possible, and that the sense amplifier dissipates the least amount of power while sensing the bit line voltage difference. More or less the external disturbances and noise will affect the sense amplifier output.

There are some conflicts in speed, power dissipation and stability in the prior art sensing scheme by using P-type device to pull up the voltage of bit line and bit line-bar during pre-charging cycle and let the N-type device of the SRAM cell to sink the current to differentiate the voltage level between bit line and bit line-bar. For ensuring the functionality of the sensing amplifier, the differential voltage between bit line and bit line-bar which are input to the sense amplifier should be high, which means the power dissipation maintains high. A lower differential voltage input to the sense amplifier would dissipate low power and save time of sinking from one of the N-type transistor of the SRAM cell but will cause higher danger of failure in the sensing amplifier.

### SUMMARY OF THE INVENTION

The present invention of a semiconductor memory sensing scheme which successfully reduces noise and power/ground bouncing and allows smaller voltage swing of bit line and bit line-bar hence avoids dissipating higher power.

The present invention of a sensing scheme discharges the bit line and bit line bar nodes much quickly through N-type devices coupling between ground and the bit line or bit line-bar during non-accessing mode. N-type devices discharge the bit line or bit line-bar quickly. This allows more time for accessing or data evaluation cycle and allows more duration time for sensing amplifier to output a more stable data.

The present invention of a sensing scheme applies a delay circuit to postpone the operation of discharging and hence to avoid overlapping between discharging the bit line (bit line-bar) and the memory cells.

According to an embodiment of this invention of the sensing scheme, since the differential input voltage to the sense amplifier is also correspondingly smaller, the P-type device in the SRAM cell pulls up the bit line or bit line-bar voltage relatively slower than conventional means of using the N-type device to pull down the bit line or bit line-bar, the time requires to obtain a stable output from a sense amplifier is very close for a P-type device to pull up or an N-type device to pull down the bit line or the bit line-bar.

According to an embodiment of this invention of the sensing scheme, one of bit line and bit line-bar nodes are pulled up much slowly by P-type transistor within an SRAM memory cell which significantly reduces noise magnitude of power supply and ground bouncing during memory cell data accessing.

According to another embodiment of this invention of the sensing scheme, an equalizer device coupling between the bit line and bit line-bar is implemented to minimize the voltage difference between the bit line and bit line-bar when they are discharging.

According to another embodiment of this invention of the sensing scheme, a self-timer circuit is implemented to pull down the word line voltage to isolate the P-type transistors within the SRAM cells from further pulling up the bit line or bit line-bar node voltage when a stable output voltage from a sense amplifier is obtained.

According to another embodiment of this invention of the sensing scheme, the self-timer circuit also quickly drives out a “discharging” signal to discharge the nodes of bit line and bit line-bar when memory array goes out of accessing mode.

Other aspects and advantages of the present invention will become apparent from the following detailed description, taken in conjunction with the accompanying drawings, illustrating by way of example the principles of the invention. It is to be understood that both the foregoing general description and the following detailed description are by examples, and are intended to provide further explanation of the invention as claimed.

### BRIEF DESCRIPTION OF THE DRAWINGS

FIG. 1 depicts the simplified block diagram of a memory bank;

FIG. 2a illustrates a simplified prior art sensing scheme of accessing a memory cell;;

FIG. 2b depicts timing of memory cell data accessing of a prior art sensing scheme;

FIG. 3 shows the timing relationship among clock, word line, pre-charging, bit line and bit line-bar, sense amplifier and its enable signal;

FIG. 4 depicts the present invention of the low power sensing scheme;

FIG. 5 depicts the timing diagram of the present invention of the low power memory scheme with pull-down discharging devices;

FIG. 6B illustrates the power supply, VDD bouncing and the ground bouncing during memory accessing;

FIG. 6A illustrates another sense amplifier circuit with a conventional analog differential amplifier;

FIG. 7 depicts a high speed, low power sense amplifier with current sensing mechanism;

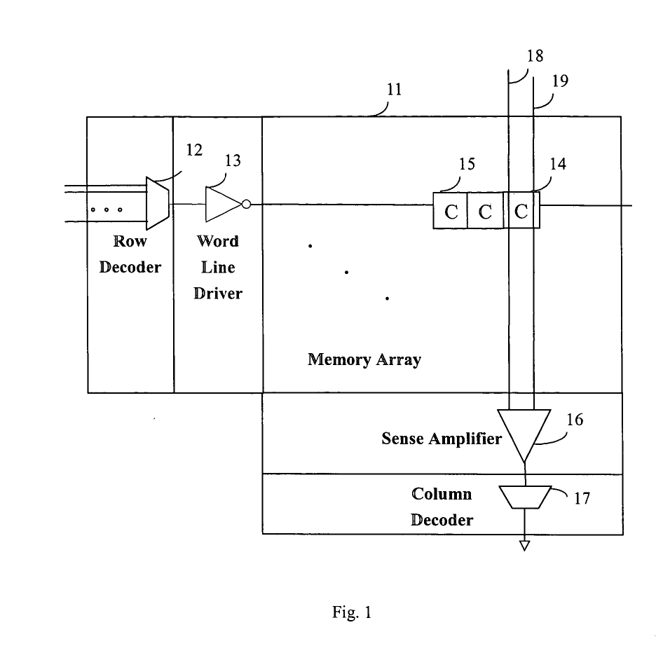

### DESCRIPTION OF THE PREFERRED EMBODIMENTS

In addition to the parasitic diode leakage current, there are two main factors consuming power in semiconductor memory circuits. The first one is differentiating the voltage between bit line and bit line-bar which are input into the sense amplifier. The other is the leak current caused by the overlapping of pre-charging and word line signal. The operation of charging and discharging the bit line and bit line-bar results in power consumption. The equation below shows the power consumption calculation. CL is the capacitive loading, f is the switching frequency which is equivalent to charging and discharging frequency, delta V is the magnitude of the voltage swing. These three factors dominate the power consumption of the memory data sensing.
P=CLΔV²×f

External noise coupled into the sense amplifier causes the sense amplifier to inadvertently switch from one output voltage potential to another output voltage potential. That is, the noise coupled into the sense amplifier causes the sense amplifier to output a wrong logic level when the bit line voltage difference is at a potential level less than a threshold level.

Clues to cause wrong output out of a sense amplifier in memory accessing include: the coupling noise, power supply and ground bouncing, pre-charging voltage level difference, unbalance voltage of the sensing path and offset voltage of a sense amplifier. That is why in a practical design, a larger voltage difference, for example, 300 mV, between bit line and bit line-bard is required to ensure a proper functionality of a sense amplifier. From the power consumption equation, it is obvious that the greater the voltage swing between pre-charging and discharging voltage levels, the more the power consumption will be. Therefore, the smaller differential between the memory cell pull-up voltage level and the discharge voltage level is critical for power consumption in memory designs. While, a smaller voltage difference input to the sense amplifier can cause error in sensing as described above. Therefore, the stability of the sensing path and the power consumption becomes conflicting requirements in the memory design.

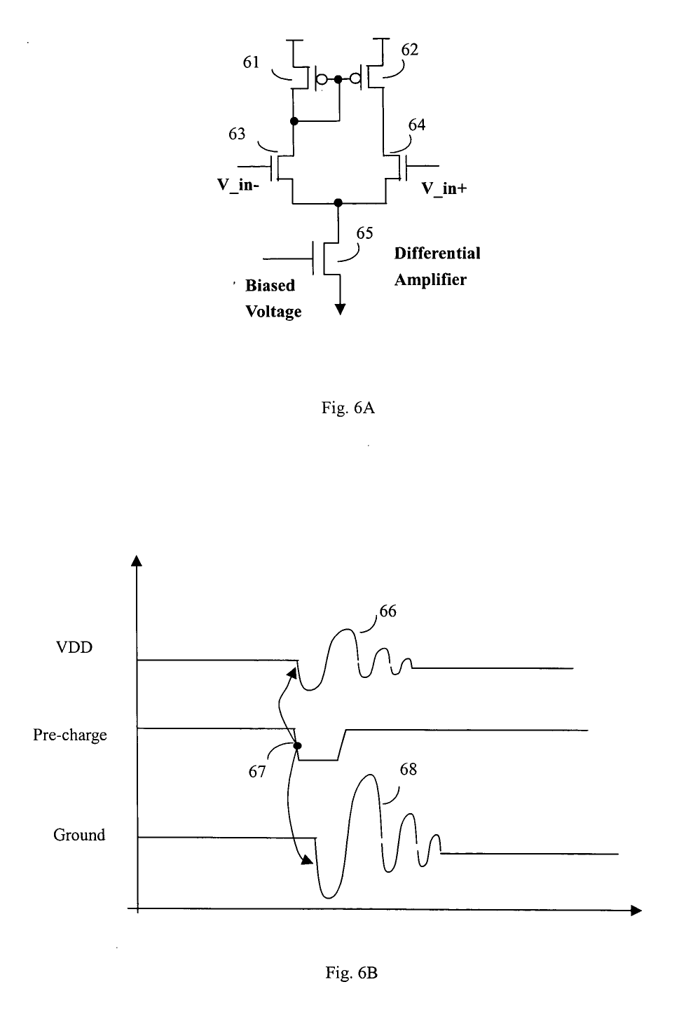

One of the main sources of the noise is the inductive current noise which is generated when current flows through parasitic inductive circuit similar to said an inductor. The higher inductance or the higher amount the current through the inductor in a certain short period of time, the higher the magnitude the noise will be generated. As shown in FIG. 6B, the power supply VDD bouncing 66 and ground bouncing 68 are very commonly show up noise caused by the inductive current noise. The VDD or ground bouncing triggered by simultaneous turning on the P-type device of the memory cell easily cause function failure of the sense amplifier which make a larger differential voltage to the sense amplifier necessary.

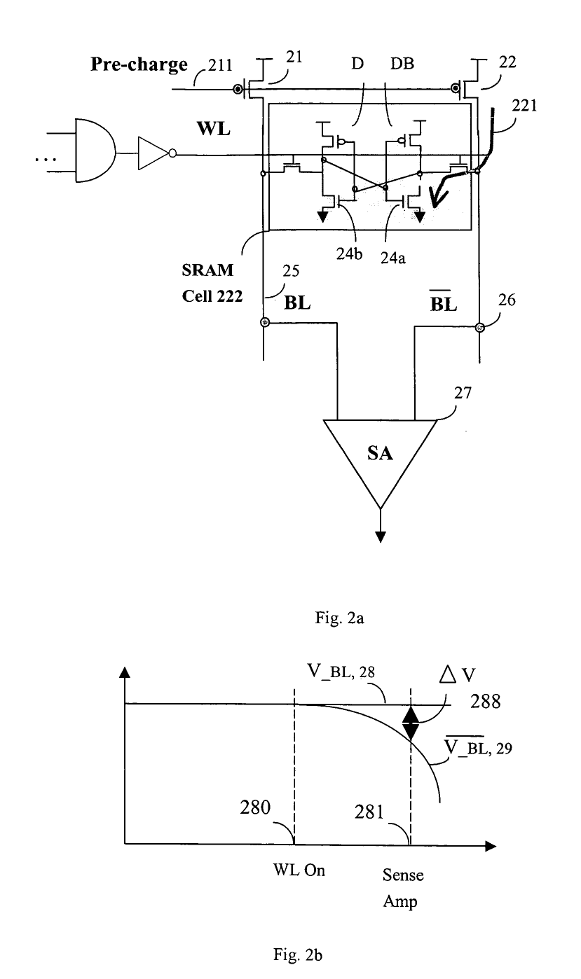

FIG. 2a depicts the simplified most commonly used prior art of sensing scheme of a memory accessing. A pre-charging signal is applied to the gates of P-type pull-up transistors 21, 22. When memory cell is no longer being accessed, the pre-charge signal becomes low and turns on the pull-up devices 21, 22 which pull bit line and bit line-bar all the way up to VDD. During reading, the word line is driven high and turns on the memory cell 222. One of the two N-type devices 24a, 24b with the gate on high voltage starts is turned on and sinking the current. The other node DB, connecting to the BL through a pass transistor will keep the same logic “High” state since node DB the BL have the same voltage level. A simplified timing diagram shown in FIG. 2b illustrates that right after word line 280 rises to high memory cells are turned on and one node of the bit line and bit line-bar starts sinking current and pulling down the pre-charged voltage level 29. Till a predetermined threshold, a differential voltage between bit line and bit line-bar 288, at that time, the sense amplifier should be able to output a stable signal, then the sense amplifier is turned enabled if a current sensing mechanism, or disabled if a conventional voltage sensing mechanism.

FIG. 6A shows a conventional analog differential sense amplifier with voltage sensing mechanism with two input devices 63, 64 hooked to the bit line and bit line-bar. The current source 65 dissipates DC current which is equivalent to the sum of currents drawing through the two P-type pull-up devices 61, 62. This kind of sense amplifier should be disabled to avoid DC current by shutting off the current source when a stable output voltage is reached.

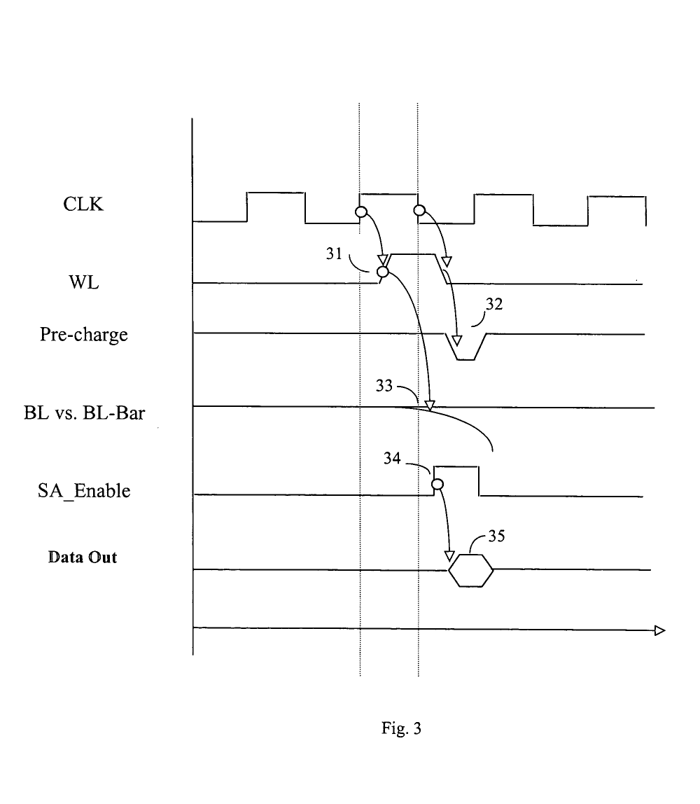

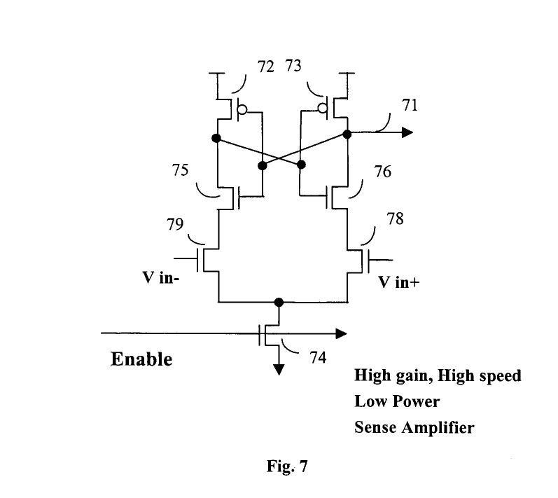

FIG. 7 illustrates a current driven sensing amplifier. The main function of this kind of sense amplifier is the back-to-back inverter like circuit comprised of two P-type devices 72, 73 and two N-type devices 75, 76. In principle, the back-to-back devices make up infinite voltage gain. Gates of the input devices 78, 79 are connected to the bit line and bit line-bar. Once the sense amplifier is enabled as the pull down device 74 is turned on, the differential voltage between V_in+ 78 and V_in− 79 are latched into the sense amplifier and the back-to-back devices quickly amplify the differential voltage to be logic “1” or “0” in the output node 71. FIG. 3 shows the timing relationship among clock, word line, pre-charging, bit line and bit line-bar, sense amplifier and its enable signal. A rising clock signal CLK drives the selected word line 31 to high and turns on all memory cells hooked on to the selected word line in the same bank of memory array. The N-type device in a memory cell starts sinking current and one node of bit line and bit line-bar starts dropping hence the voltage between bit line and bit line-bar is differentiated 33. Once the output data 35 of the sense amplifier becomes stable, the sense amplifier is disabled by the control of a self-timer. A self-timer is comprised of some delay devices for instance, a capacitor for controlling the output signal at a predetermined time.

The kind of commonly used sensing scheme with P-type pull-up devices to pre-charge bit lines and bit line-bars consumes higher power during memory accessing since the N-type transistor of the memory cell sinks the current quickly with thousands of bit line get discharged simultaneously and cause higher coupling noise and requires larger differential voltage between the bit line and the bit line-bar to ensure the accuracy of the sense amplifier. Overlapping between pre-charging and word line is another cause of current leakage. During overlapping, current might flow through the pull-up transistors to the memory cells. The longer the duration of overlapping between pre-charge and word line signals, the more current will be leaked.

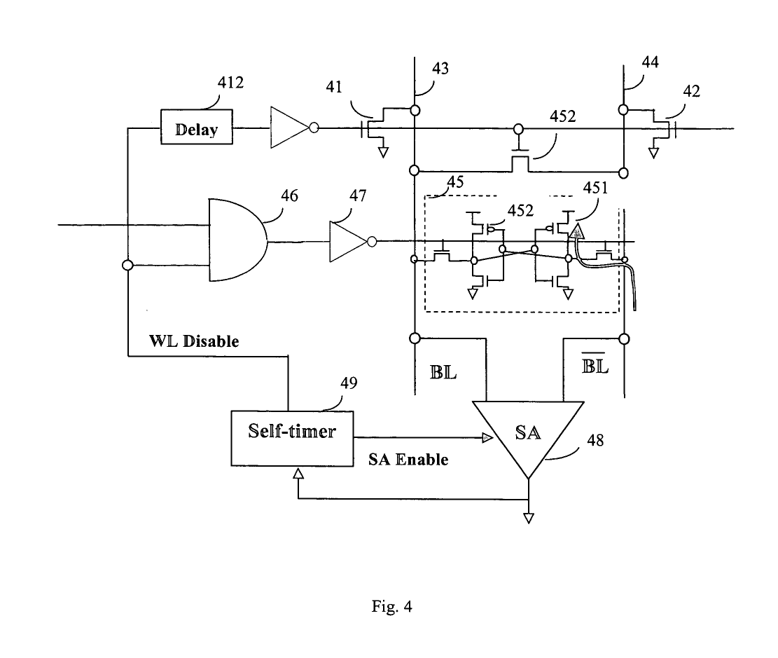

FIG. 4 depicts the circuit according to the present invention of a low power and low noise sensing scheme. Two N-type devices 41, 42 discharge the bit line 43 and bit line-bar 44 all the way down to ground after data accessing operation is done. During the accessing period, one of the two P-type transistors 451, 452 of the memory cell 45 pulls the bit line 43 or bit line-bar 44 voltage level up to differentiate the voltage difference between bit line and the bit line-bar which is also the differential voltage input to the sense amplifier. Since the P-type transistor has intrinsically higher resistance value compared to its counterpart, N-type transistor, the current flowing through the memory cell to VDD is smaller in this present sensing scheme, then the coupling noise, VDD or ground bounce caused by inductive current is hence smaller. The noise reduction helps in allowing smaller differential voltage input to the sense amplifier hence saves the power consumption. Another N-type device 452 coupled between bit line and bit line-bar is implemented as an equalizer to short the bit line and bit line-bar and to ensures minimum voltage difference between bit line and bit line-bar during non-accessing mode.

According to an embodiment of the present invention, a self-timer 49 is implemented to disable the word line decoder 46 and to pull down the word line driver 47 when the memory cell pulls one node of the bit line and the bit line-bar high enough, for example, said 150 mV, to allow the sense amplifier to function properly. The self-timer enables a current sensing dynamic sense amplifier 48 when the differential voltage between bit line and bit line-bar reaches the predetermined threshold value. Overlapping phenomenon might cause current leaking by drawing current from memory cell to ground through the pull-down devices 41, 42. Since there could be hundreds or even thousands of memory cells hooked to a word line, a bit line or a bit line-bar, a heavy capacitive load of word line or bit line and bit line-bar makes it easy for overlapping phenomenon between word line and pull-down devices happen. In the present invention, a delay device 412 is used to avoid overlapping between pull down devices 41, 42 and word line driver 47 which helps in avoid leaking current flowing from memory cell to ground through the pull-down devices 41, 42. A delay device is comprised of a long length and slow transistor or easily implemented by a capacitor which is commonly used to slow down the speed of charging and discharging.

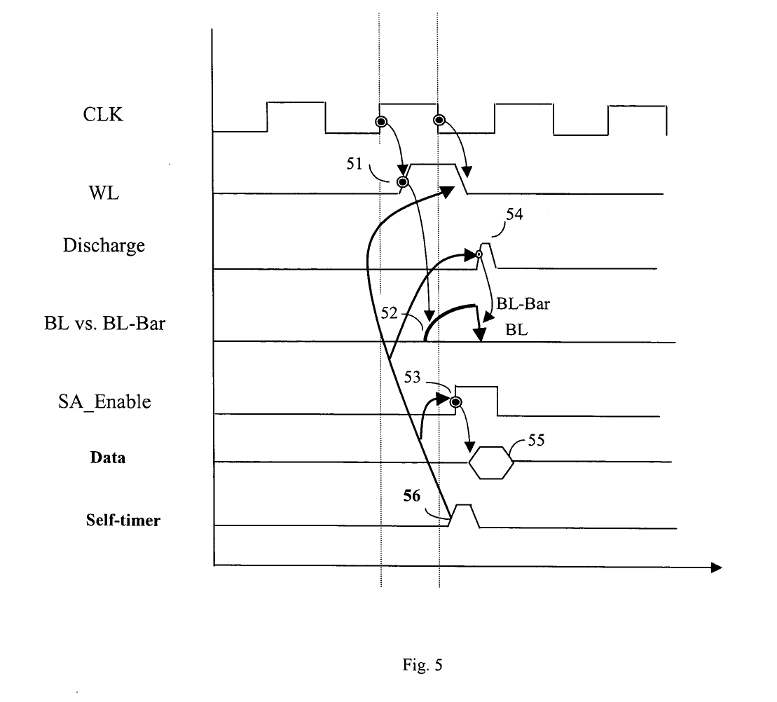

The corresponding timing diagram of the present invention of a low power memory sensing scheme is shown in FIG. 5. During data accessing period, a rising clock signal, CLK drives the selected word line 51 to high and turns on all memory cells hooked to this selected word line. The P-type device in a memory cell starts pulling up voltage of one node of bit line and bit line-bar. When the differential voltage 52 between the bit line and bit line-bar reaches a predetermined threshold, said 200 mV, the self-timer drives out an “SA_Enable” signal to enable the current driven sense amplifier and to latch out the accessed data 55. After a little delay, the “Discharge” signal 54 pulls all bit lines and bit line-bars within a bank of the same memory array through the N-type pull-down devices. Since this invention uses the P-type device of a memory cell to pull up the bit line or bit line-bar slow and hence minimize the coupling noise and VDD/Ground bouncing. Since the discharging operation through the N-type devices is very fast, this leaves more time for data accessing within a same clock cycle time. The required differential voltage between bit line and bit line-bar is hence reduced. Therefore, even the P-type device is slow than it counterpart of an N-type device, the time needs to differentiate voltage to a smaller threshold is close to that of larger threshold through the N-type device. The fast discharging plus the smaller differential voltage required to input to the sense amplifier make the present sensing scheme competitive speed in data accessing compare to its prior art sensing scheme with P-type devices of pre-charging the bit lines and bit line-bars.

It will be apparent to those skills in the art that various modifications and variations can be made to the structure of the present invention without departing from the scope or the spirit of the invention. In the view of the foregoing, it is intended that the present invention cover modifications and variations of this invention provided they fall within the scope of the following claims and their equivalents.

1. A semiconductor memory sensing circuit in a memory array, comprising:
at lease one memory cell of a memory array, that generates a first voltage output and a second voltage output when the memory cell is accessed, wherein the first voltage output ramps from a predetermined voltage level to a higher voltage level, and the second voltage output keeps in a predetermined voltage level;
a first N-type device coupled between ground and one corresponding bit line of the memory array;
a second N-type device coupled between ground and one corresponding bit line-bar of the memory array; and
a differential amplifier with two input nodes coupled to the bit line and the bit line-bar of the memory array to generate a first sense output voltage if the first voltage output of one memory cell is higher than a second voltage output of the one memory cell and to generate a second sense output voltage if the first voltage output of one memory cell is lower than a second voltage output of the one memory cell.

2. The circuit as recited in claim 1, wherein the memory cell has at least one semiconductor device.

3. The circuit as recited in claim 1, wherein the memory cell has a static random access memory (SRAM) device.

4. The circuit as recited in claim 3, wherein the SRAM cell has at least one back-to-back inverting circuit with both inverting devices hooked up to VDD through a pull-up device and to Ground through a pull-down device.

5. The circuit as recited in claim 4, wherein the pull-up device has a P-type semiconductor device and the pull-down device has an N-type semiconductor device.

6. The circuit as recited in claim 4, wherein the pull-up device has a resistor and the pull-down device has another resistor.

7. The circuit as recited in claim 1, wherein the differential amplifier has an amplifier circuit with at least two differential input nodes and a control input for enabling and disabling the amplifier circuit.

8. A control circuit for a semiconductor memory array, comprising:
a sense amplifier for amplifying output from a memory cell; and
a self-timer coupled to the sense amplifier for counting a time and sending out control signals to shut off the sense amplifier according to the time and pulling down a word line to avoid further current sinking through the memory cell.

9. The circuit as recited in claim 8, further comprising
a delay device for controlling a second time to discharge a bit line and a bit line-bar of the memory array;

10. The circuit as recited in claim 8, wherein the self-timer counts the time of differentiating a voltage between the bit line and the bit line-bar.

11. The circuit as recited in claim 8, wherein when the differential voltage of the bit line and the bit line-bar reaches a predetermined threshold, the self-timer sends a signal to turn off the word line.

12. The circuit as recited in claim 8, wherein when the differential voltage of the bit line and the bit line-bar reaches a predetermined threshold, the self-timer sends a signal to enable the sense amplifier.

13. The circuit as recited in claim 9, wherein when the differential voltage of the bit line and the bit line-bar reaches a predetermined threshold, the delay device send a signal to discharge the bit line and bit line-bar.

14. The circuit as recited in claim 9, wherein the delay device postpones the time and sends a signal to turn on N-type devices to discharge the bit line and bit line-bar to avoid overlapping of the word line and the bit line and bit line-bar.
